(19) United States
(12) Patent Application Publication
(10) Pub. No.: US 2003/0042624 A1
(43) Pub. Date: Mar. 6, 2003

(54) Power semiconductor device

(75) Inventor: Toshiaki Shinohara, Fukuoka (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/207,022

(22) Filed: Jul. 30, 2002

(30) Foreign Application Priority Data
Aug. 28, 2001 (JP) 2001-257798

(51) Int. Cl. H01L 23/28

(52) U.S. Cl. 257/787

(57) ABSTRACT

A power semiconductor device having a power element sealed into a package, which comprises the package, the power element fixed in the package, a bonding wire connected to the power element, and a gel insulator for covering the power element, characterized in that foam material is further charged so as to fill a cavity left inside of said package.

### CROSS-REFERENCE TO RELATED APPLICATIONS

A related patent application is a commonly assigned Japanese Patent Application No. 2001-257798 filed on Aug. 28, 2001, which is incorporated by reference into the present patent application.

### BACKGROUND OF THE INVENTION

1. Field of the Invention

The present invention relates to a power semiconductor device, and more particularly to a power semiconductor device provided with vibration-proof.

2. Description of the Related Art

FIG. 3 is a sectional view of a conventional power semiconductor device indicated in its entirety as 500. Power semiconductor device 500 includes a heat spreader plate 1. Onto the heat spreader plate 1, an insulation substrate 2 is connected via a solder layer 6. The insulation substrate has wiring patterns 4 and 5 formed on both sides of a ceramic substrate 3. Onto the wiring pattern 4, power elements 7 are connected via a solder layer 8.

On the heat spreader plate 1, a case 9 is provided so as to surround the insulation substrate 2. The case 9 has a terminal 10. The terminal 10 and wiring pattern 4, as well as the terminal 10 and power elements 7 are connected via bonding wires 11. Silicone gel 12 is charged inside of the case 9 so as to embed the insulation substrate 2, the power elements 7, and the bonding wires 11. On the other hand, the part that is not filled with silicon gel 12 is left as hollow part 20.

In addition, a shield board 13 and a control board 14 are fixed inside of the case 9. On the control board 14, control elements 15 are provided and coupled to the power elements 7 via a relay terminal 16. On the control board 14, a signal terminal 17 is provided.

Over the case 9, a cover 18 is provided. The signal terminal 17 projects outside from a hole (not shown) provided through the cover 18. The heat spreader plate 1, the case 9, and the cover 18 form a package.

When the power semiconductor device 500 is mounted on a train or an automobile and used therein, external vibrations at frequencies of approx. 20 Hz to 2,000 Hz are applied to the power semiconductor device 500. Therefore, resonance occurs in soft silicone gel 12, and the shield board 13 and the control board 14 both screwed onto the case 9, at predetermined respective characteristic frequencies thereof. As a result, the amplitude of the vibration of the silicon gel 12 or the like is larger than those of the external vibrations applied thereto. This phenomenon poses a problem, such as breakage of bonding wires 11 in the silicon gel 12, and failure of the control board 14 or the relay terminal 16.

### SUMMARY OF THE INVENTION

Therefore, the present invention aims to provide a power semiconductor device preventing the constituent components from failure caused by the resonance thereof when the device is used under such conditions that external vibrations are applied thereto.

In accordance with one aspect of the present invention, there is provided a power semiconductor device having a power element sealed into a package. The power semiconductor device includes: the package; the power element fixed in the package; a bonding wire connected to the power element; and a gel insulator for covering the power element. The power semiconductor device is characterized in that foam material is charged so as to fill a cavity left inside of the package.

In accordance with another aspect of the present invention, there is provided another power semiconductor device having a power element sealed into a package. The power semiconductor device includes: the package; the power element fixed in the package; and a bonding wire connected to the power element. In addition, the power semiconductor device is characterized in that foam material is charged so as to fill a cavity in the package.

### BRIEF DESCRIPTION OF THE DRAWINGS

FIG. 1 is a cross sectional view of a power semiconductor device in accordance with a first preferred embodiment of the present invention;

FIG. 2 is a cross sectional view of a power semiconductor device in accordance with a second preferred embodiment of the present invention; and

FIG. 3 is a cross sectional view of a conventional power semiconductor device.

### DETAILED DESCRIPTION OF THE PREFERRED EMBODIMENTS

### First Preferred Embodiment

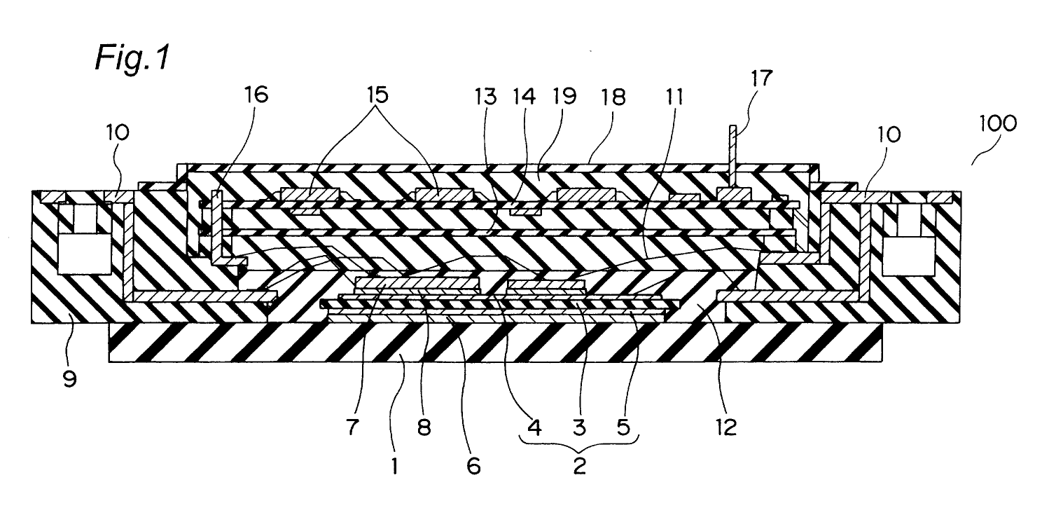

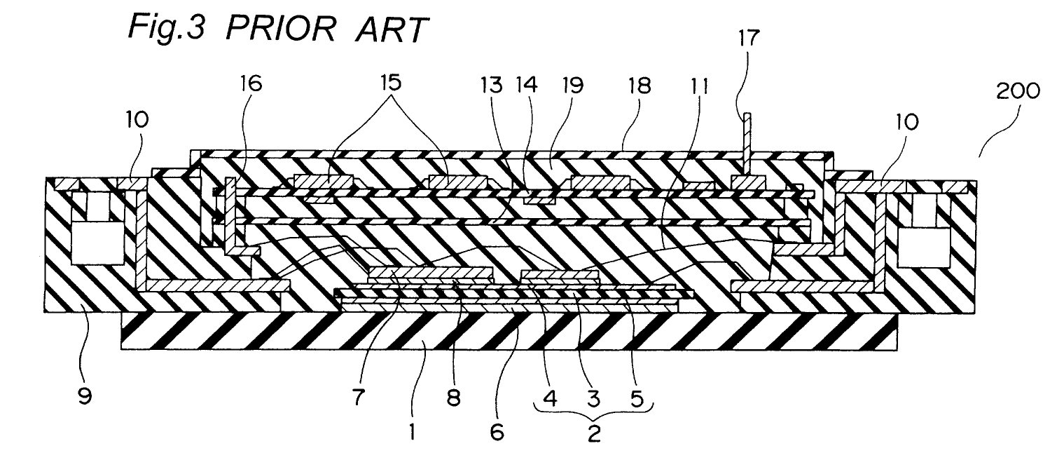

FIG. 1 is a sectional view of a power semiconductor device in accordance with this embodiment indicated in its entirety as 100. In the drawing, reference numerals like those shown in FIG. 3 refer to similar or corresponding elements.

The power semiconductor device 100 includes heat spreader plate 1. The heat spreader plate 1 is made of copper or aluminum. Onto the heat spreader plate 1, an insulation substrate 2 is connected via a solder layer 6. The insulation substrate has wiring patterns 4 and 5 formed on both sides of a ceramic substrate 3. The ceramic substrate 3 is made of aluminum nitride, alumina, or other materials. Each of wiring patterns 4 and 5 is made of a thin layer of copper or aluminum. Onto the wiring pattern 4, power elements 7, such as an insulated gate bipolar transistor (IGBT) and a diode, are connected via solder layers 8.

On heat spreader plate 1, a case 9 is provided so as to surround an insulation substrate 2. In the case 9, terminal 10 for external elicitation is provided. The terminal 10 is integrated into the case 9 when the case 9 is formed. The connections of the wiring pattern 4 or the power elements 7 with the terminal 10, are formed via bonding wires 11 made of aluminum, for example. So are the wiring pattern 4 or the power elements 7 with the relay terminal 16.

In addition, a shield board 13 and a control board 14 are fixed inside of the case 9. On the control board 14, control elements 15 are provided and coupled to the power elements 7 via the relay terminal 16. The control board 14 and the relay terminal 16 are connected by solder, for example. Provided on the control board 14 is a signal terminal 17 for inputting external control signals into the control elements 15.

Over the case 9, a cover 18 is provided. The signal terminal 17 projects outside from a hole (not shown) provided through the cover 18.

Inside of the case 9, silicone gel 12 is charged so as to cover the power elements 7. Covering the power elements 7 with the highly insulating silicone gel 12 in this manner can maintain the insulating properties between the terminals of the power elements 7.

In addition, polyurethane foam 19 is charged so as to fill the cavity above the silicon gel 12. The polyurethane foam 19 is charged so as to cover bonding wires 11, the shield board 13, the control board 14, and the relay terminal 16, and other components.

The polyurethane foam 19 has a low density ranging from approx. 25 kg/m³ to 50 kg/m³. For this reason, the characteristic frequency of the polyurethane foam 19 largely differs from the frequencies (approx. 20 Hz to 2,000 Hz) of external vibrations applied to the power semiconductor device 100 when the device is mounted on an automobile. Thus, the resonance does not occur in the device even when external vibrations are applied thereto.

Furthermore, because the polyurethane foam 19 is of closed-cell type, the insulating properties thereof can be maintained higher than those of an open-cell type.

In addition, the shield board 13 and other components are in contact with the polyurethane foam 19. This increases the rigidity of the shield board 13 and other components. Therefore, the characteristic frequencies of the shield board 13 and other components can be excluded from a frequency range of external vibrations applied to the device and the resonance of the shield board 13 and other components can be prevented or reduced.

Even when the characteristic frequencies of the shield board 13 and other components cannot be excluded from the frequency range of external vibrations applied to the device, the amplitudes of the shield board 13 and other components can be reduced.

Moreover, the vibration of the silicon gel 12 is inhibited by the contact thereof with the polyurethane foam 19.

Especially in this embodiment, as many of the bonding wires 11 as possible are covered with the polyurethane foam 19. Thus, even when the silicon gel 12 vibrates, the vibration of bonding wires 11 is inhibited and the breakage of bonding wires 11 can be prevented.

As mentioned above, with the power semiconductor device 100 in accordance with this embodiment, even when it is used under such conditions that external vibrations are applied, resonance of the constituent components thereof can be inhibited and the failure thereof can be prevented.

JP, 3-112153, A discloses a memory module having foam material charged inside of a case thereof. However, the formed material is used as cushioning material for absorbing external shocks or vibrations applied to the device. Unlike the power semiconductor device 100, the formed material does not aim to inhibit or prevent the resonance. Especially, unlike the power semiconductor device 100, the memory module is not intended to be used under such conditions that continuous vibrations are applied.

### Second Preferred Embodiment

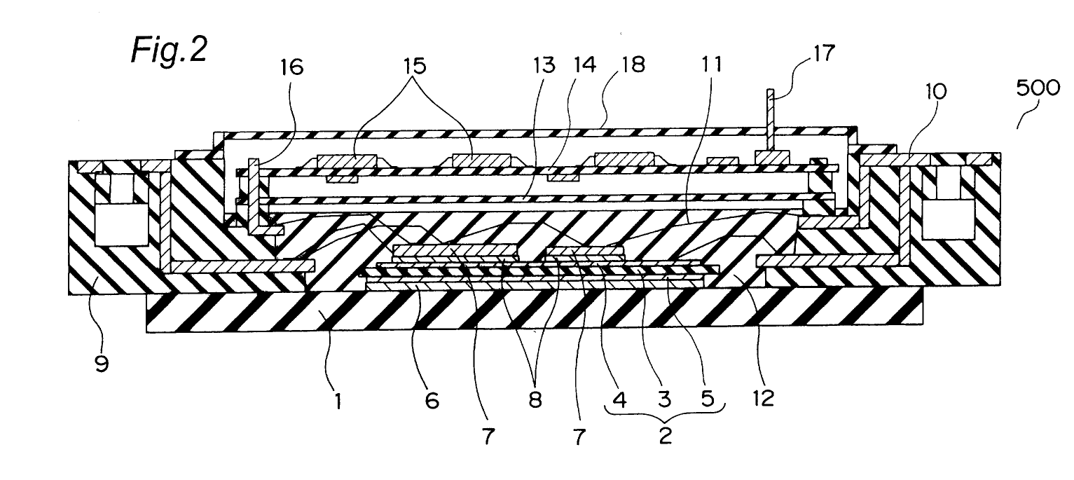

FIG. 2 is a sectional view of a power semiconductor device of this embodiment indicated in its entirety as 200. In the drawing, reference numerals like those as shown in FIG. 1 refer to similar or corresponding elements.

With power semiconductor device 200, the surroundings of power elements 7 or other components are embedded with polyurethane foam 19 only, and no silicon gel is used.

While the use of the polyurethane foam 19 instead of silicon gel slightly reduces insulation characteristics of the device, it can improve vibration absorption characteristics. For example, when the interval of the electrodes for high voltage application is wide, the use of the polyurethane foam 19 instead of the silicone gel can provide sufficient insulating characteristics.

In First and Second Preferred Embodiments, the power semiconductor devices 100 and 200 having the shield board 13 and the control board 14 are described. The present invention can be implemented in a power semiconductor device that does not include these components. In this case, the damage to bonding wires caused by vibrations can be prevented.

What is claimed is:

1. A power semiconductor device having a power element sealed into a package, comprising:
said package;
said power element fixed in said package;
a bonding wire connected to said power element; and
a gel insulator for covering said power element;
characterized in that foam material is further charged so as to fill a cavity left inside of said package.

2. A power semiconductor device according to claim 1, further comprising:
a control board for controlling said power element; and
a shield board provided between said power element and said control board;
characterized in that said control board and said shield board are sealed into said foam material.

3. A power semiconductor device according to claim 1, characterized in that said bonding wire is sealed into said foam material.

4. A power semiconductor device according to claim 1, characterized in that the characteristic frequency of said foam material is out of a range of approx. 20 Hz to 2,000 Hz.

5. A power semiconductor device according to claim 1, characterized in that the foam material is made of polyurethane foam.

6. A power semiconductor device according to claim 6, characterized in that the density of the polyurethane foam is within a range from approx. 25 kg/m³ to 50 kg/m³.

7. A power semiconductor device according to claim 1, characterized in that the foam material is closed-cell foam material.

8. A power semiconductor device according to claim 1, characterized in that said gel insulator is silicone gel.

9. A power semiconductor device having a power element sealed into a package, comprising:
said package;
said power element fixed in said package; and
a bonding wire connected to said power element;
characterized in that foam material is further charged so as to fill a cavity left inside of said package.

10. A power semiconductor device according to claim 10, further comprising:
a control board for controlling said power element; and
a shield board provided between said power element and said control board;
characterized in that said control board and said shield board are sealed into said foam material.

11. A power semiconductor device according to claim 10, characterized in that said bonding wire is sealed into said foam material.

12. A power semiconductor device according to claim 10, characterized in that the characteristic frequency of said foam material is out of a range of approx. 20 Hz to 2,000 Hz.

13. A power semiconductor device according to claim 10, characterized in that the foam material is made of polyurethane foam.

14. A power semiconductor device according to claim 15, characterized in that the density of the polyurethane foam is within a range from approx. 25 kg/m³ to 50 kg/m³.

15. A power semiconductor device according to claim 10, characterized in that the foam material is closed-cell foam material.

16. A power semiconductor device according to claim 10, characterized in that said gel insulator is silicone gel.
